(19) United States
(12) Patent Application Publication
(10) Pub. No.: US 2015/0016082 A1
(43) Pub. Date: Jan. 15, 2015

(54) PRINTED CIRCUIT BOARD AND METHOD OF MANUFACTURING THE SAME

(71) Applicant: SAMSUNG ELECTRO-MECHANICS CO., LTD., Suwon (KR)

(72) Inventor: Jae Soo LEE, Suwon (KR)

(73) Assignee: SAMSUNG ELECTRO-MECHANICS CO., LTD., Suwon (KR)

(21) Appl. No.: 14/300,795

(22) Filed: Jun. 10, 2014

(30) Foreign Application Priority Data
Jul. 9, 2013 (KR) 10-2013-0080440

(51) Int. Cl. H05K 1/18; H05K 1/11

(52) U.S. Cl. CPC H05K 1/18; H05K 1/115
USPC 361/783; 174/262; 174/260

(57) ABSTRACT

A printed circuit board includes an insulating layer; a via in the insulating layer, a first circuit layer formed at a first side of the insulating layer and having a portion buried in the via; a second circuit layer formed at a second side of the insulating layer and electrically connected with the portion of the first circuit layer in the via.

### CROSS REFERENCE TO RELATED APPLICATION

This application claims the benefit of Korean Patent Application No. 10-2013-0080440, filed on Jul. 9, 2013, entitled “Printed Circuit Board and Method of Manufacturing the Same”, which is hereby incorporated by reference in its entirety into this application.

### BACKGROUND OF THE INVENTION

1. Technical Field

Embodiments of present invention relate to a printed circuit board and a method of manufacturing the same.

2. Description of the Related Art

In accordance with the development of an electronic industry, improvement of performance and functions of electronic components and miniaturization of the electronic components have been demanded. Therefore, a board for a high density surface mounting component such as a semiconductor packet, or the like, has been prominent. As described above, in order to satisfy the demand for an increase in density of the board and thinness of the board, high density interlayer connection of circuit patterns is required.

A technology by plating is a scheme of processing a via hole and then plating an inner peripheral surface of the via hole or filling a plating layer in the via hole to implement interlayer connection.

However, the above-mentioned related art has a limitation in the high density interlayer connection, it may not be applied as a complete production technology.

A structure capable of implementing an increase in density of a circuit by increasing density of an interlayer connection of circuit patterns or a degree of freedom of a circuit design has been demanded.

### CITATION LIST

(Patent Document 1) US Patent Publication No. 2012/0152753 A1

### SUMMARY OF THE INVENTION

The present invention has been made in an effort to provide a semiconductor package in which circuit patterns capable of serving as a land are buried in a via of a semiconductor package substrate, and a method of manufacturing the same.

According to one embodiment of the present invention, there is provided a printed circuit board including: an insulating layer; a first circuit layer including first circuit patterns and second circuit patterns buried in a first surface of the insulating layer so that upper surfaces thereof are exposed; a second circuit layer including third circuit patterns and fourth circuit patterns formed on a second surface of the insulating layer; and vias electrically connecting the second circuit patterns and the fourth circuit patterns to each other and formed in the insulating layer so that the second circuit patterns are buried therein.

Heights of the first and second circuit patterns may be lower than that of the insulating layer, such that a step is formed between the first and second circuit patterns and the insulating layer.

The second circuit pattern may serve as a land.

The second circuit pattern may have a width equal to or smaller than a diameter of the via.

The via and the second circuit pattern may be made of the same material.

The printed circuit board may further include a solder resist formed to expose circuit patterns for a connection pad in the first circuit layer and the second circuit layer.

The printed circuit board may further include a build-up layer stacked on the second surface of the insulating layer.

According to another embodiment of the present invention, there is provided a semiconductor package including: an insulating layer; a first circuit layer including first circuit patterns and second circuit patterns buried in a first surface of the insulating layer so that upper surfaces thereof are exposed; a second circuit layer including third circuit patterns and fourth circuit patterns formed on a second surface of the insulating layer; vias electrically connecting the second circuit patterns and the fourth circuit patterns to each other and formed in the insulating layer so that the second circuit patterns are buried therein; and an electronic component connected to and mounted on the first circuit layer.

According to another embodiment of the present invention, there is provided a semiconductor package including: an insulating layer; a first circuit layer including first circuit patterns and second circuit patterns buried in a first surface of the insulating layer so that upper surfaces thereof are exposed; a second circuit layer including third circuit patterns and fourth circuit patterns formed on a second surface of the insulating layer; vias electrically connecting the second circuit patterns and the fourth circuit patterns to each other and formed in the insulating layer so that the second circuit patterns are buried therein; an electronic component connected to and mounted on the first circuit pattern; solder bumps formed on the second circuit patterns; and an upper semiconductor package connected to and mounted on the solder bumps.

According to another embodiment of the present invention, there is provided a method of manufacturing a printed circuit board, including: preparing a carrier substrate; forming first metal layers on both surfaces of the carrier substrate; forming first circuit layers on both surfaces of the first metal layers, the first circuit layer including first and second circuit patterns; sequentially forming insulating layers and second metal layers on the first circuit layers; forming via holes in the second metal layers and the insulating layers so that the second circuit patterns are exposed; forming vias and patterned metal plating layers so that the second circuit patterns are buried therein; separating the carrier substrate and the first metal layers from each other; and removing the first and second metal layers to expose the first circuit layers and forming second circuit layers including third and fourth circuit patterns.

According to another embodiment of the present invention, there is provided a method of manufacturing a semiconductor package, including: preparing a carrier substrate; forming first metal layers on both surfaces of the carrier substrate; forming first circuit layers on both surfaces of the first metal layers, the first circuit layer including first and second circuit patterns; sequentially forming insulating layers and second metal layers on the first circuit layers; forming via holes in the second metal layers and the insulating layers so that the second circuit patterns are exposed; forming vias and patterned metal plating layers so that the second circuit patterns are buried therein; separating the carrier substrate and the first metal layers from each other; removing the first and second metal layers to expose the first circuit layers and forming second circuit layers including third and fourth circuit patterns; and mounting an electronic component on the first circuit layer.

According to another embodiment of the present invention, there is provided a method of manufacturing a semiconductor package, including: preparing a carrier substrate; forming first metal layers on both surfaces of the carrier substrate; forming first circuit layers on both surfaces of the first metal layers, the first circuit layer including first and second circuit patterns; sequentially forming insulating layers and second metal layers on the first circuit layers; forming via holes in the second metal layers and the insulating layers so that the second circuit patterns are exposed; forming vias and patterned metal plating layers so that the second circuit patterns are buried therein; separating the carrier substrate and the first metal layers from each other; removing the first and second metal layers to expose the first circuit layers and forming second circuit layers including third and fourth circuit patterns; mounting an electronic component on the first circuit patterns; forming solder bumps on the second circuit patterns; and mounting an upper semiconductor package on the solder bumps.

Heights of the first and second circuit patterns may be lower than that of the insulating layer, such that a step is formed between the first and second circuit patterns and the insulating layer.

The second circuit pattern may serve as a land.

The second circuit pattern may have a width equal to or smaller than a diameter of the via.

The via and the second circuit pattern may be made of the same material.

The method may further include forming build-up layers on the second circuit layers.

The forming of the first circuit layers may include: forming resist layers on the first metal layers, the resist layer including opening parts for forming a circuit; forming circuit layers in the opening parts; and removing the resist layers.

According to one embodiment of the present invention, there is provided a printed circuit board including: an insulating layer; a first circuit layer formed at one side of the insulating layer and a second circuit layer formed at the other side of the insulating layer; and vias formed to penetrate through the insulating layer to electrically connect the first and second circuit layers to each other, wherein the first circuit layer includes a circuit pattern at least a portion of which is buried in the via.

the via has a tapered shape in which one side thereof has a width smaller than that of the other side thereof, and the circuit pattern is buried in one side of the via.

the circuit pattern is buried in the via so that one surface thereof is exposed.

the first circuit layer further includes a circuit pattern at least a portion of which is buried in the insulating layer.

one surface of the circuit pattern buried in the insulating layer is exposed.

the second circuit layer includes a circuit pattern protruding on the other side of the insulating layer.

the first circuit layer has a height lower than that of the insulating layer, such that a step is formed between the first circuit layer and the insulating layer.

Additional aspects and/or advantages will be set forth in part in the description which follows and in part will be apparent from the description or may be learned by practice of the invention.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view showing a structure of a printed circuit board according to one embodiment of the present invention;

FIG. 2 is a cross-sectional view showing a structure of a semiconductor package according to another embodiment of the present invention;

FIG. 3 is a cross-sectional view showing a structure of a semiconductor package according to another embodiment of the present invention;

FIG. 4 is a cross-sectional view showing a structure of a semiconductor package according to another embodiment of the present invention;

FIG. 5 is a cross-sectional view showing a structure of a printed circuit board according to another embodiment of the present invention; and

FIGS. 6 to 15 are cross-sectional views sequentially showing a method of manufacturing a semiconductor package according to another preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

Printed Circuit Board and a Semi-Conductor Using the Same

the printed circuit board 100 according to the one embodiment of the present invention is configured to include an insulating layer 140, a first circuit layer 135 formed at one side of the insulating layer 140 and a second circuit layer 136 formed at the other side of the insulating layer 140 and vias 170 formed to penetrate through the insulating later 140 to electrically connect the first and second circuit layers to each other, the first circuit layer 135 includes a circuit pattern at least a portion of which is buried in the via.

Here, the via 170 has a tapered shape in which one side thereof has a width smaller than that of the other side thereof, and the circuit pattern 132 is buried in one side of the via 170.

In addition, the circuit pattern 135 is buried in the via 170 so that one surface thereof is exposed.

In addition, the first circuit layer 135 further includes a circuit pattern at least a portion of which is buried in the insulating layer 140.

Here, one surface of the circuit pattern buried in the insulating layer 140 is exposed.

In addition, the second circuit layer 136 includes a circuit pattern protruding on the other side of the insulating layer 140.

In addition, the first circuit layer 135 has a height lower than that of the insulating layer 140, such that a step is formed between the first circuit layer and the insulating layer 140.

Printed Circuit Board

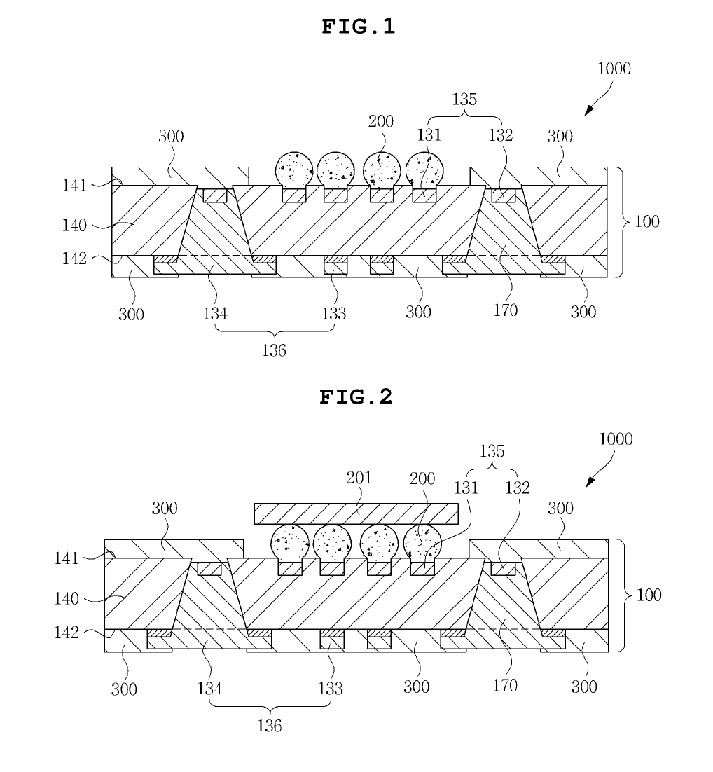

FIG. 1 is a cross-sectional view showing a structure of a printed circuit board according to a embodiment of the present invention.

FIGS. 2 to 5 are cross-sectional views showing a structure of a semiconductor package according to the embodiment of the present invention.

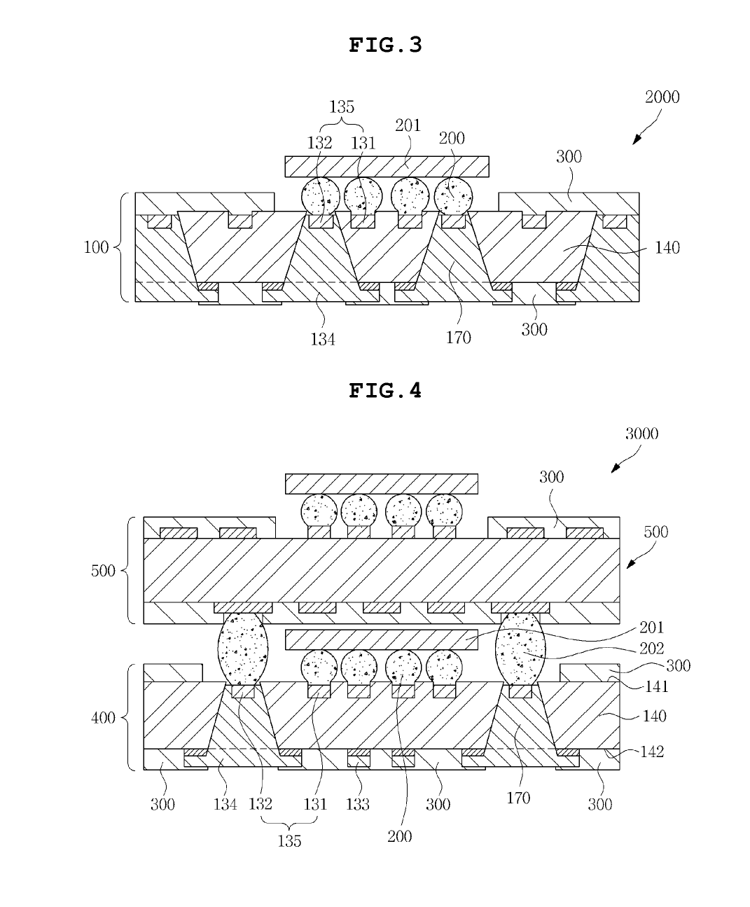

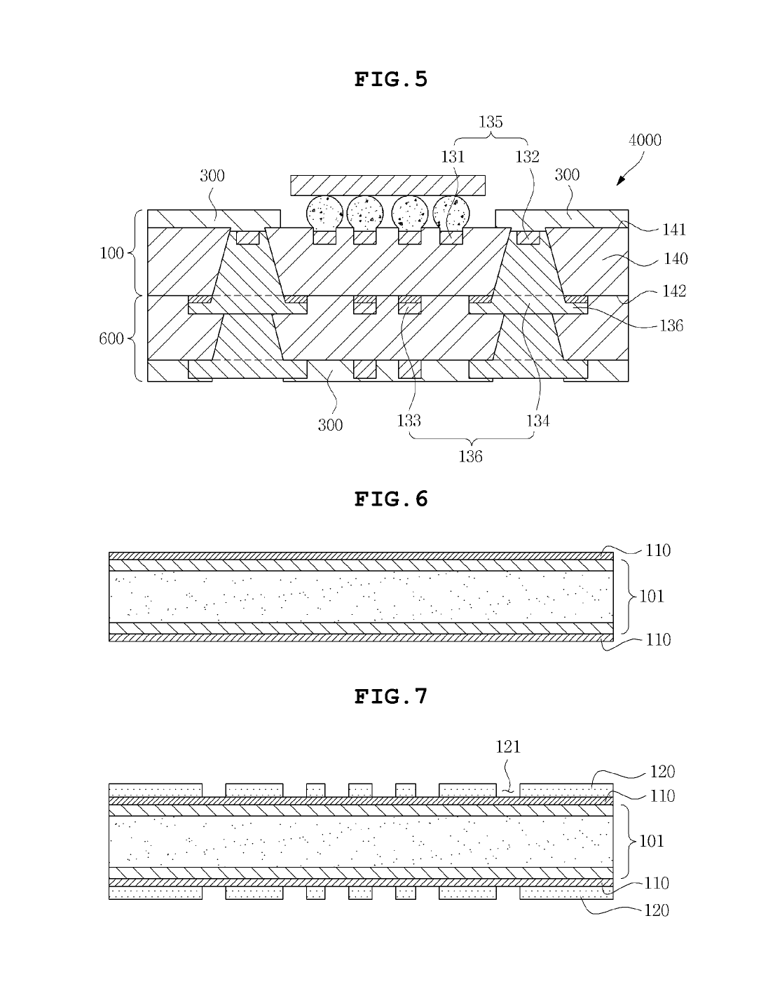

FIG. 1 is a cross-sectional view showing a structure of a printed circuit board according to a first embodiment of the present invention; FIG. 2 is a cross-sectional view showing a structure of a semiconductor package according to another embodiment of the present invention; FIG. 3 is a cross-sectional view showing a structure of a semiconductor package according to another embodiment of the present invention; FIG. 4 is a cross-sectional view showing a structure of a semiconductor package according to another embodiment of the present invention; and FIG. 5 is a cross-sectional view showing a structure of a semiconductor package according to another embodiment of the present invention.

As shown in FIG. 1, the printed circuit board 100 according to one embodiment of the present invention is configured to include an insulating layer 140, a first circuit layer 135 including first circuit patterns 131 and second circuit patterns 132 buried in a first surface 141 of the insulating layer 140 so that upper surfaces thereof are exposed, a second circuit layer 136 including third circuit patterns 133 and fourth circuit patterns 134 formed on a second surface 142 of the insulating layer 140, vias 170 electrically connecting the second circuit patterns 132 and the fourth circuit patterns 134 to each other and formed in the insulating layer 140 so that the second circuit patterns 132 are buried therein, solder bumps 200 formed on the first circuit patterns 131, and a solder resist 300 formed to expose circuit patterns for a connection pad in the first circuit layer 135 and the second circuit layer 136.

As the insulating layer 140, a resin insulating layer may be used. As a material of the resin insulating layer, a thermo-setting resin such as an epoxy resin, a thermo-plastic resin such as a polyimide resin, a resin having a reinforcement material such as a glass fiber or an inorganic filler impregnated in the thermo-setting resin and the thermo-plastic resin, for example, a prepreg may be used. In addition, a thermo-setting resin, a photo-curable resin, and the like, may be used. However, the material of the resin insulating layer is not specifically limited thereto.

The circuit layers 135 and 136 may be made of any conductive metal for a circuit used in a circuit board field and be made of copper in the case of a printed circuit board.

A surface treatment layer (not shown) may be further formed on the exposed circuit layer if necessary.

The surface treatment layer may be any surface treatment layer known in the art and be formed through, for example, electro gold plating, immersion gold plating, organic solderability preservative (OSP) or immersion tin plating, immersion silver plating, electroless nickel and immersion gold (ENIG), direct immersion gold (DIG) plating, hot air solder leveling (HASL), or the like.

Here, the second circuit pattern 132 is manufactured so as to serve as a land. Therefore, since more circuits may be formed in a limited region by burying the second circuit pattern 132 in the via 170, a high density product may be produced.

In addition, the second circuit pattern 132 is formed to have a width smaller than a diameter of the via 170, such that only an upper surface of the second circuit pattern 132 is exposed to the outside and three surfaces of the second circuit pattern 132 other than the upper surface are buried in the via 170, thereby making it possible to improve electrical characteristics and reliability of the semiconductor package.

The via 170 may be made of the same material as that of the second circuit pattern 132. The via is typically made of copper (Cu), but may also be made of any conductive metal.

In addition, although the case in which the via 170 has a tapered shape in which a diameter thereof becomes larger in a downward direction has been shown in FIG. 1, the via 170 may also have all shapes known in the related art, such as a tapered shape in which a diameter thereof becomes smaller in the downward direction, a circular shape, and the like.

In addition, a height of the exposed upper surface of the first circuit layer 135 is lower than that of the insulating layer 140, such that a step may be formed between the first circuit layer 135 and the insulating layer 140.

Here, a solder is fixed by the step in a reflow process for forming the solder bump 200 on the first circuit pattern 131, thereby making it possible to prevent a bridge phenomenon between solders adjacent to each other.

As shown in FIG. 2, the semiconductor package 2000 according another embodiment of the present invention is configured to include a printed circuit board 100 including an insulating layer 140, a first circuit layer 135 including first circuit patterns 131 and second circuit patterns 132 buried in a first surface 141 of the insulating layer 140 so that upper surfaces thereof are exposed, a second circuit layer 136 including third circuit patterns 133 and fourth circuit patterns 134 formed on a second surface 142 of the insulating layer 140, vias 170 electrically connecting the second circuit patterns 132 and the fourth circuit patterns 134 to each other and formed in the insulating layer 140 so that the second circuit patterns 132 are buried therein, an electronic component 201 connected to and mounted on the first circuit patterns 131 by solder bumps 200, and a solder resist 300 formed to expose the first circuit layer 135 and the second circuit layer 136.

The electronic component 201, which is a component electrically connected to the printed circuit board to perform a predetermined function, indicates an electronic component capable of being mounted on the printed circuit board, such as an integrated circuit (IC) chip.

Although the electronic component 201 has been schematically shown without other detailed components in FIG. 2, electronic components having all structures known in the art may be used without specific restriction.

Here, the second circuit pattern 132 is manufactured so as to serve as a land. Therefore, since more circuits may be formed in a limited region by burying the second circuit pattern 132 in the via 170, a high density product may be produced.

In addition, the second circuit pattern 132 is formed to have a width smaller than a diameter of the via 170, such that only an upper surface of the second circuit pattern 132 is exposed to the outside and three surfaces of the second circuit pattern 132 other than the upper surface are buried in the via 170, thereby making it possible to improve electrical characteristics and reliability of the semiconductor package.

The via 170 may be made of the same material as that of the second circuit pattern 132. The via is typically made of copper (Cu), but may also be made of any conductive metal.

In addition, although the case in which the via 170 has a tapered shape in which a diameter thereof becomes larger in the downward direction has been shown in FIG. 2, the via 170 may also have all shapes known in the related art, such as a tapered shape in which a diameter thereof becomes smaller in the downward direction, a circular shape, and the like.

In addition, a height of the exposed upper surface of the first circuit layer 135 is lower than that of the insulating layer 140, such that a step may be formed between the first circuit layer 135 and the insulating layer 140.

Here, a solder is fixed by the step in a reflow process for forming the solder bump 200 on the first circuit pattern 131, thereby making it possible to prevent a bridge phenomenon between solders adjacent to each other.

As shown in FIG. 3, the semiconductor package 3000 according to another embodiment of the present invention is configured to include a printed circuit board 100 including an insulating layer 140, a first circuit layer 135 including first circuit patterns 131 and second circuit patterns 132 buried in a first surface 141 of the insulating layer 140 so that upper surfaces thereof are exposed, a second circuit layer 136 including third circuit patterns 133 and fourth circuit patterns 134 formed on a second surface 142 of the insulating layer 140, vias 170 electrically connecting the second circuit patterns 132 and the fourth circuit patterns 134 to each other and formed in the insulating layer 140 so that the second circuit patterns 132 are buried therein, an electronic component 201 connected to and mounted on the first circuit patterns 131 and the second circuit patterns 132 by solder bumps 200, and a solder resist 300 formed to expose the first circuit layer 135 and the second circuit layer 136.

Here, the second circuit pattern 132 is manufactured so as to serve as a land. Therefore, since more circuits may be formed in a limited region by burying the second circuit pattern 132 in the via 170, a high density product may be produced.

In addition, the second circuit pattern 132 is formed to have a width smaller than a diameter of the via 170, such that only an upper surface of the second circuit pattern 132 is exposed to the outside and three surfaces of the second circuit pattern 132 other than the upper surface are buried in the via 170, thereby making it possible to improve electrical characteristics and reliability of the semiconductor package.

The via 170 may be made of the same material as that of the second circuit pattern 132. The via is typically made of copper (Cu), but may also be made of any conductive metal.

In addition, although the case in which the via 170 has a tapered shape in which a diameter thereof becomes larger in the downward direction has been shown in FIG. 3, the via 170 may also have all shapes known in the related art, such as a tapered shape in which a diameter thereof becomes smaller in the downward direction, a circular shape, and the like.

In addition, a height of the exposed upper surface of the first circuit layer 135 is lower than that of the insulating layer 140, such that a step may be formed between the first circuit layer 135 and the insulating layer 140.

Here, a solder is fixed by the step in a reflow process for forming the solder bump 200 on the first circuit pattern 131, thereby making it possible to prevent a bridge phenomenon between solders adjacent to each other.

As shown in FIG. 4, the semiconductor package 4000 according to another embodiment of the present invention is configured to include a printed circuit board 100 including an insulating layer 140, a first circuit layer 135 including first circuit patterns 131 and second circuit patterns 132 buried in a first surface 141 of the insulating layer 140 so that upper surfaces thereof are exposed, a second circuit layer 136 including third circuit patterns 133 and fourth circuit patterns 134 formed on a second surface 142 of the insulating layer 140, vias 170 electrically connecting the second circuit patterns 132 and the fourth circuit patterns 134 to each other and formed in the insulating layer 140 so that the second circuit patterns 132 are buried therein, an electronic component 201 connected to and mounted on the first circuit patterns 131, solder bumps 202 formed on the second circuit patterns 132, and an upper semiconductor package 500 connected to and mounted on the solder bumps 202.

Here, the second circuit pattern 132 is manufactured so as to serve as a land. Therefore, since more circuits may be formed in a limited region by burying the second circuit pattern 132 in the via 170, a high density product may be produced.

In addition, the second circuit pattern 132 is formed to have a width smaller than a diameter of the via 170, such that only an upper surface of the second circuit pattern 132 is exposed to the outside and three surfaces of the second circuit pattern 132 other than the upper surface are buried in the via 170, thereby making it possible to improve electrical characteristics and reliability of the semiconductor package.

The via 170 may be made of the same material as that of the second circuit pattern 132. The via is typically made of copper (Cu), but may also be made of any conductive metal.

In addition, although the case in which the via 170 has a tapered shape in which a diameter thereof becomes larger in the downward direction has been shown in FIG. 4, the via 170 may also have all shapes known in the related art, such as a tapered shape in which a diameter thereof becomes smaller in the downward direction, a circular shape, and the like.

In addition, a height of the exposed upper surface of the first circuit layer 135 is lower than that of the insulating layer 140, such that a step may be formed between the first circuit layer 135 and the insulating layer 140.

Here, a solder is fixed by the step in a reflow process for forming the solder bump 200 on the first circuit pattern 131, thereby making it possible to prevent a bridge phenomenon between solders adjacent to each other.

The upper semiconductor package 500 is not particularly limited, but may be a package in which a general semiconductor is mounted. The upper semiconductor package 500 has a typical package on package (POP) structure in which it is connected to a lower semiconductor package 400 through the solder bump 202.

As shown in FIG. 5, the semiconductor package 5000 according to another embodiment of the present invention is configured to include a printed circuit board 100 including an insulating layer 140, a first circuit layer 135 including first circuit patterns 131 and second circuit patterns 132 buried in a first surface 141 of the insulating layer 140 so that upper surfaces thereof are exposed, a second circuit layer 136 including third circuit patterns 133 and fourth circuit patterns 134 formed on a second surface 142 of the insulating layer 140, vias 170 electrically connecting the second circuit patterns 132 and the fourth circuit patterns 134 to each other and formed in the insulating layer 140 so that the second circuit patterns 132 are buried therein, an electronic component 201 connected to and mounted on the first circuit patterns 131 by solder bumps 200, and solder resists 300 formed on both surfaces of the printed circuit substrate 100 so as to expose circuit patterns for a connection pad in the first circuit layer 135 and the second circuit layer 136. In addition, the semiconductor package 5000 according to another embodiment further includes a build-up layer 600 stacked on the second surface 142 of the insulating layer 140.

Here, the second circuit pattern 132 is manufactured so as to serve as a land. Therefore, since more circuits may be formed in a limited region by burying the second circuit pattern 132 in the via 170, a high density product may be produced.

In addition, the second circuit pattern 132 is formed to have a width smaller than a diameter of the via 170, such that only an upper surface of the second circuit pattern 132 is exposed to the outside and three surfaces of the second circuit pattern 132 other than the upper surface are buried in the via 170, thereby making it possible to improve electrical characteristics and reliability of the semiconductor package.

The via 170 may be made of the same material as that of the second circuit pattern 132. The via is typically made of copper (Cu), but may also be made of any conductive metal.

In addition, although the case in which the via 170 has a tapered shape in which a diameter thereof becomes larger in the downward direction has been shown in FIG. 5, the via 170 may also have all shapes known in the related art, such as a tapered shape in which a diameter thereof becomes smaller in the downward direction, a circular shape, and the like.

In addition, a height of the exposed upper surface of the first circuit layer 135 is lower than that of the insulating layer 140, such that a step may be formed between the first circuit layer 135 and the insulating layer 140.

Here, a solder is fixed by the step in a reflow process for forming the solder bump 200 on the first circuit pattern 131, thereby making it possible to prevent a bridge phenomenon between solders adjacent to each other.

Here, although the case in which the build-up layer 600 stacked on the second surface 142 of the insulating layer includes two layers, that is, a build-up insulating layer and a build-up circuit layer, has been shown in FIG. 5, the build-up layer may also include three layers, four layers, or layers selectable by those skilled in the art.

Method of Manufacturing Printed Circuit Board

FIGS. 6 to 16 are cross-sectional views sequentially showing a method of manufacturing a semiconductor package according to another embodiment of the present invention.

As shown in FIG. 6, a carrier substrate 101 is prepared.

The carrier substrate 101 may be made of a copper clad laminate (CCL), but is not particularly limited thereto.

Here, first metal layers 110 are formed on both surfaces of the carrier substrate 101.

The first metal layer 110 may be made of copper (Cu), but is not particularly limited thereto.

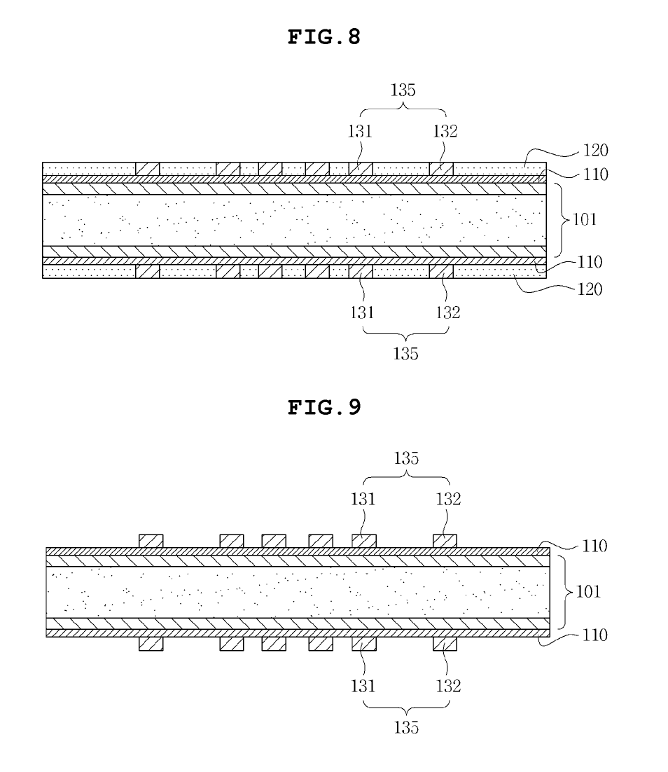

As shown in FIG. 7, a resist layer 120 having opening parts 121 for forming circuits may be formed on the first metal layer 110.

The resist layer 120, which is a general photosensitive resist film, may be made of a dry film resist, or the like, but is not particularly limited thereto.

As shown in FIG. 8, a first circuit layer 135 may be formed by filling the opening part with a metal, for example, by using a process such as a plating process, or the like.

Here, the circuit layer may be made of any conductive metal for a circuit and is typically made of copper (Cu) in the printed circuit board.

As shown in FIG. 9, the resist layer 120 for forming circuits may be removed.

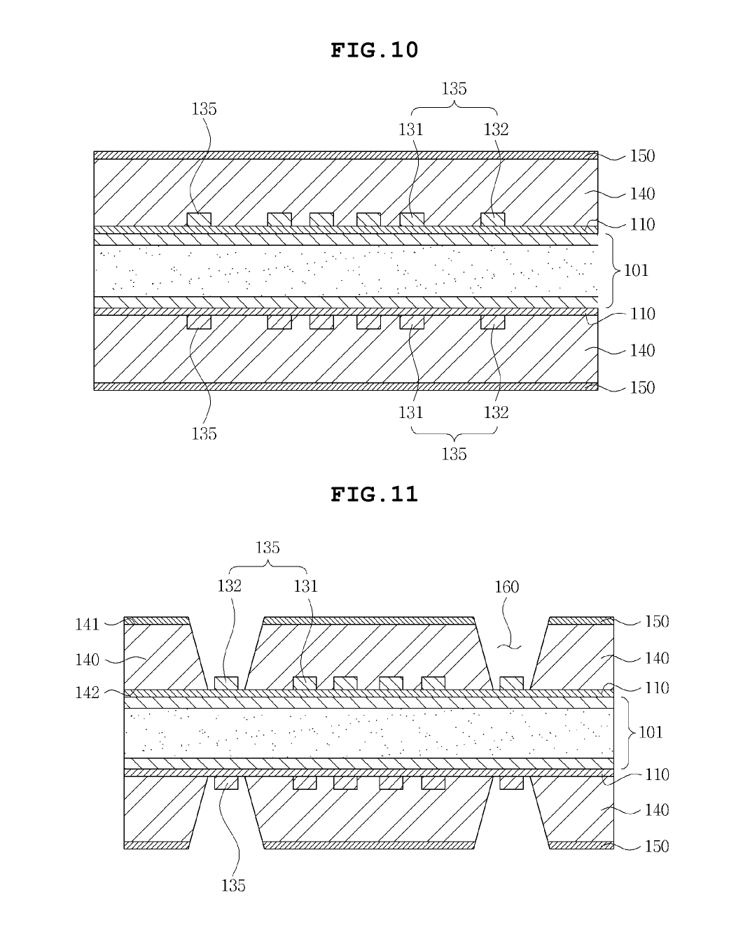

As shown in FIG. 10, an insulating layer 140 and a second metal layer 150 may be sequentially formed on the first circuit layer 135.

As the insulating layer 140, a resin insulating layer may be used. As a material of the resin insulating layer, a thermo-setting resin such as an epoxy resin, a thermo-plastic resin such as a polyimide resin, a resin having a reinforcement material such as a glass fiber or an inorganic filler impregnated in the thermo-setting resin and the thermo-plastic resin, for example, a prepreg may be used. In addition, a thermo-setting resin, a photo-curable resin, and the like, may be used. However, the material of the resin insulating layer is not specifically limited thereto.

As shown in FIG. 11, via holes 160 may be formed in the second metal layer 150 and the insulating layer 140 so that second circuit patterns 132 in the first circuit layer 135 are exposed.

Here, the via hole 160 may be formed using a mechanical drill or a laser drill, but is not particularly limited thereto. Here, the laser drill may be a CO₂ laser drill or a YAG laser drill, but is not limited thereto.

In addition, although the case in which the via 170 has a tapered shape in which a diameter thereof becomes larger in the downward direction has been shown in FIG. 11, the via 170 may also have all shapes known in the related art, such as a tapered shape in which a diameter thereof becomes smaller in the downward direction, a circular shape, and the like.

Here, at the time of forming the via hole 160, the via hole 160 may be formed to have a diameter larger than a width of the second circuit pattern 132.

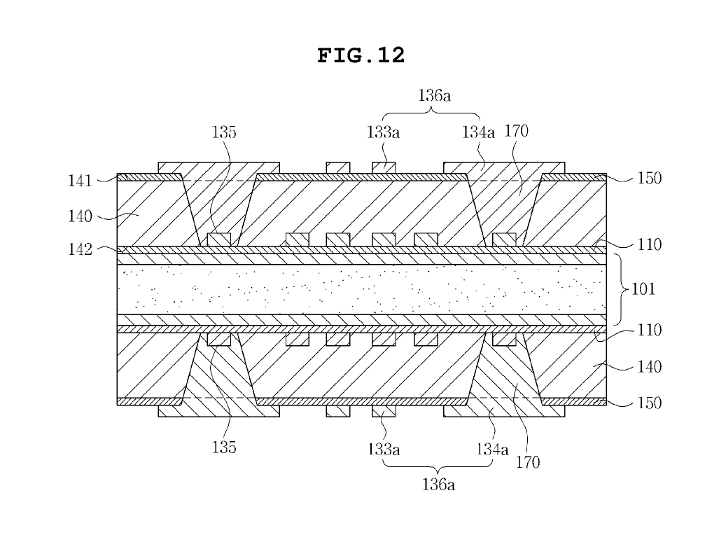

As shown in FIG. 12, vias 170 and patterned metal plating layers 133a, 134a, and 136a may be formed so that the second circuit patterns 132 are buried therein.

Here, a metal material filled in the via 170 may be the same material as that of the buried second circuit pattern 132.

Here, since the second circuit pattern 132 substituting for a land is present in the via hole 160, an advantageous effect for a via fill at the time of filling the metal material may be generated.

Here, only an upper surface of the second circuit pattern 132 is exposed to the outside and surfaces of the second circuit pattern 132 other than the upper surface are buried in the via 170, thereby making it possible to improve electrical characteristics and reliability of the semiconductor package.

In addition, the second circuit pattern 132 is manufactured so as to serve as a land. Therefore, since more circuits may be formed in a limited region by burying the second circuit pattern 132 in the via hole 160, a high density product may be produced.

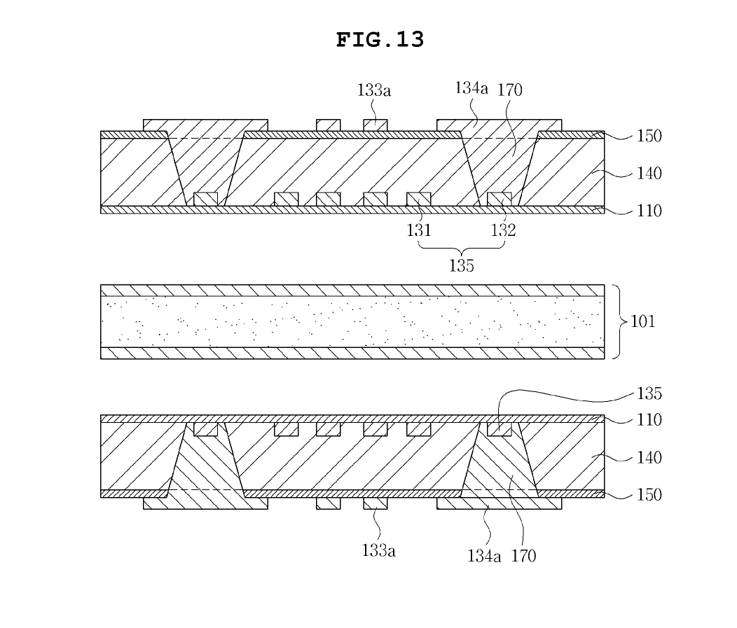

As shown in FIG. 13, the carrier substrate 101 the first metal layer 110 may be separated from each other.

Although the case in which the carrier substrate 101 the first metal layer 110 are separated from each other using a blade has been described in the present embodiment, the carrier substrate 101 the first metal layer 110 may also be separated from each other by all methods known in the art.

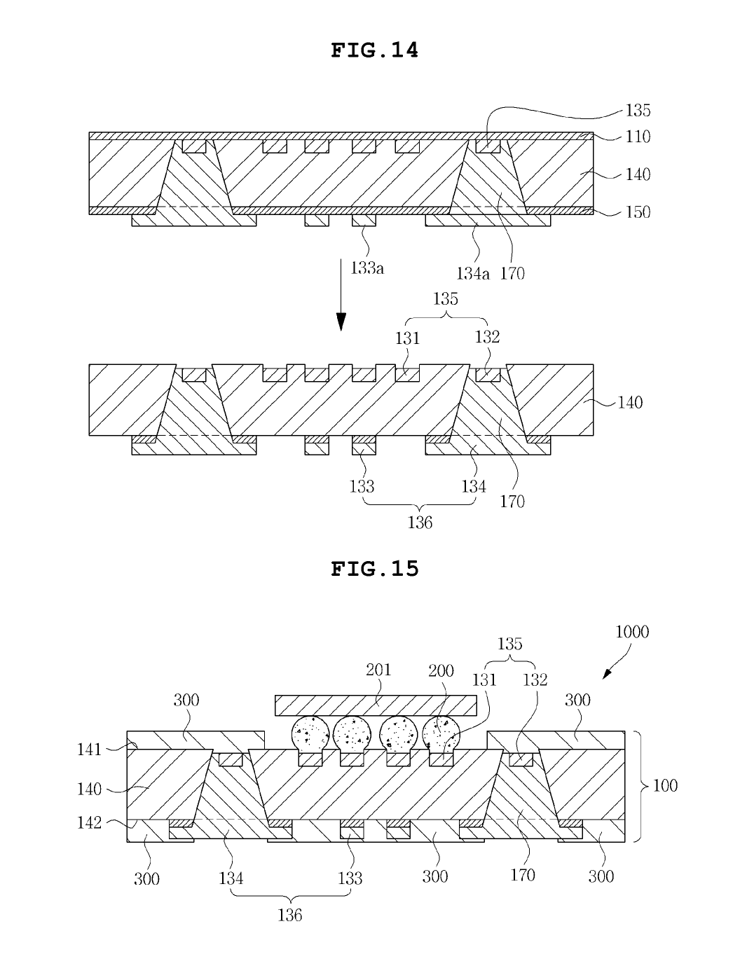

As shown in FIG. 14, the first and second metal layers 110 and 150 may be removed to expose the first circuit layer 135, and a second circuit layer 136 including third circuit patterns 133 and fourth circuit patterns 134 may be formed.

More specifically, it may be sufficiently recognized by those skilled in the art that the second metal layer 150 may be selectively removed only in a portion in which the metal plating layer 136a is not formed, by general flash etching.

The first and second metal layers 110 and 150 may be removed by an etching process, but is not particularly limited thereto. Here, a step may be formed between the first circuit layer 135 and the insulating layer 140 in a process of etching the first metal layer 110.

Here, a solder is fixed by the step in a reflow process for forming a solder bump 200 on the first circuit pattern 131, thereby making it possible to prevent a bridge phenomenon between solders adjacent to each other.

Although not shown, a build-up layer may be stacked on the second surface 142 of the insulating layer 140.

Here, although the case in which the build-up layer stacked on the second surface 142 of the insulating layer includes two layers has been shown, the build-up layer may also include three layers, four layers, or layers selectable by those skilled in the art.

As shown in FIG. 15, solder resists 300 may be formed on both surfaces of the insulating layer 140 so as to expose circuit patterns for a connection pad in the first and second circuit layers 135 and 136.

An electronic component 201 may be mounted on the first circuit pattern 131 through the solder bump 200.

The electronic component 201, which is a component electrically connected to the printed circuit board to perform a predetermined function, indicates an electronic component capable of being mounted on the printed circuit board, such as an IC chip.

Although the electronic component 201 has been schematically shown without other detailed components in FIG. 15, electronic components having all structures known in the art may be used without specific restriction.

Since the circuit pattern is manufactured so as to serve as a land, the circuit pattern is buried in the via, such that more circuits may be formed in a limited region. As a result, a high density product may be produced.

In addition, the circuit pattern is formed to have a width smaller than a diameter of the via, such that only an upper surface of the circuit pattern is exposed to the outside and three surfaces of the circuit pattern other than the upper surface are buried in the via, thereby making it possible to improve electrical characteristics and reliability of the semiconductor package.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

1. A printed circuit board comprising:
an insulating layer;
a first circuit layer including first circuit patterns in recessed portion of the insulating layer on a first side of the insulating layer and second circuit patterns in a first side of the insulating layer;
a second circuit layer including third circuit patterns and fourth circuit patterns formed on a second side of the insulating layer; and
vias electrically connecting the second circuit patterns and the fourth circuit patterns to each other and formed in the insulating layer so that the second circuit patterns are in the vias.

2. The printed circuit board according to claim 1, wherein the second circuit patterns are in recessed portions of the vias.

3. The printed circuit board according to claim 1, wherein upper surfaces of the first and second circuit patterns are recessed from the insulating layer, such that a step is formed between the first and second circuit patterns and the insulating layer.

4. The printed circuit board according to claim 1, wherein the second circuit pattern serves as a land.

5. The printed circuit board according to claim 1, wherein the second circuit pattern has a width equal to or smaller than a diameter of the via.

6. The printed circuit board according to claim 1, wherein the via and the second circuit pattern are made of the same material.

7. The printed circuit board according to claim 1, further comprising a solder resist formed to expose circuit patterns for a connection pad in the first circuit layer and the second circuit layer.

8. The printed circuit board according to claim 1, further comprising a build-up layer stacked on the second surface of the insulating layer.

9. A semiconductor package comprising:
an insulating layer;
a first circuit layer including first circuit patterns in recessed portions of the insulating layer on a first side of the insulating layer and second circuit patterns in a first side of the insulating layer;
a second circuit layer including third circuit patterns and fourth circuit patterns formed on a second surface of the insulating layer;
vias electrically connecting the second circuit patterns and the fourth circuit patterns to each other and formed in the insulating layer so that the second circuit patterns are in the vias; and
an electronic component connected to and mounted on the first circuit layer.

10. A semiconductor package comprising:
an insulating layer;
a first circuit layer including first circuit patterns in recessed portions of the insulating layer on a first side of the insulating layer and second circuit patterns in a first side of the insulating layer; and
a second circuit layer including third circuit patterns and fourth circuit patterns formed on a second surface of the insulating layer;
vias electrically connecting the second circuit patterns and the fourth circuit patterns to each other and formed in the insulating layer so that the second circuit patterns are in the vias;
an electronic component connected to and mounted on the first circuit pattern;
solder bumps formed on the second circuit patterns; and
an upper semiconductor package connected to and mounted on the solder bumps.

11. A method of manufacturing a printed circuit board, comprising:
forming a first metal layers on both surfaces of a carrier substrate;
forming a first circuit layer on both respective surfaces of both of the first metal layers, the first circuit layers each including first and second circuit patterns;
sequentially forming an insulating layer and then a second metal layer on both of the first circuit layers;
forming via holes in both of the second metal layers and both of the insulating layers so that the second circuit patterns are exposed;
forming vias in the via holes and forming patterned metal plating layers so that the second circuit patterns are buried in the vias;
separating the carrier substrate and the first metal layers from each other; and
removing the first and second metal layers to expose the first circuit layers and forming second circuit layers. Each including third and fourth circuit patterns from the patterned metal plating layers.

12. A method of manufacturing a semiconductor package, comprising:
forming a first metal layer on both surfaces of a carrier substrate;
forming a first circuit layer on both respective surfaces of both of the first metal layers, the first circuit layers each including first and second circuit patterns;
sequentially forming an insulating layers and then a second metal layers on both of the first circuit layers;
forming via holes in both of the second metal layers and both of the insulating layers so that the second circuit patterns are exposed;
forming vias in the via holes and forming patterned metal plating layers so that the second circuit patterns are buried in the vias;
separating the carrier substrate and the first metal layers from each other;
removing the first and second metal layers to expose the first circuit layers;
forming second circuit layers each including third and fourth circuit patterns from the patterned metal plating layers; and
mounting an electronic component on at least one of the first circuit layers.

13. A method of manufacturing a semiconductor package, comprising:
forming a first metal layer on both surfaces of a carrier substrate;
forming a first circuit layer on respective surfaces of both of the first metal layers, the first circuit layers each including first and second circuit patterns;
sequentially forming an insulating layers and then a second metal layers on both of the first circuit layers;
forming via holes in both of the second metal layers and both of the insulating layers so that the second circuit patterns are exposed;
forming vias in the via holes and forming patterned metal plating layers so that the second circuit patterns are buried in the vias;
separating the carrier substrate and the first metal layers from each other;
removing the first and second metal layers to expose the first circuit layers;
forming second circuit layers each including third and fourth circuit patterns from the patterned metal plating layers;
mounting an electronic component on at least one of the first circuit patterns;
forming solder bumps on at least one of the second circuit patterns; and
mounting an upper semiconductor package on the solder bumps.

14. The method according to claim 11, wherein heights of the first and second circuit patterns are lower than that of the respective insulating layer, such that a step is formed between the first and second circuit patterns and the respective insulating layer.

15. The method according to claim 11, wherein the second circuit pattern serves as a land.

16. The method according to claim 11, wherein the second circuit pattern has a width equal to or smaller than a diameter of the via.

17. The method according to claim 11, wherein the via and the second circuit pattern are made of the same material.

18. The method according to claim 11, further comprising forming build-up layers on the second circuit layers.

19. The method according to claim 11, wherein the forming of the first circuit layers includes:
forming resist layers on the first metal layers, the resist layer including opening parts for forming a circuit;
forming circuit layers in the opening parts; and
removing the resist layers.

20. A printed circuit board comprising:
an insulating layer;
a first circuit layer formed at one side of the insulating layer and a second circuit layer formed at the other side of the insulating layer; and
vias penetrating through the insulating layer to electrically connect the first and second circuit layers to each other,
wherein the first circuit layer includes a circuit pattern at least a portion of which is in the via.

21. The printed circuit board according to claim 20, wherein the via has a tapered shape in which one side thereof has a width smaller than that of the other side thereof, and the circuit pattern is in one side of the via.

22. The printed circuit board according to claim 21, wherein the circuit pattern is recessed in the via.

23. The printed circuit board according to claim 20, wherein the first circuit layer further includes a circuit pattern at least a portion of which is in the insulating layer.

24. The printed circuit board according to claim 23, wherein one surface of the circuit pattern is recessed in the insulating layer.

25. The printed circuit board according claim 20, wherein the second circuit layer includes a circuit pattern protruding on the other side of the insulating layer.

26. The printed circuit board according to claim 20, wherein an upper surface of the first circuit layer is recessed from the insulating layer, such that a step is formed between the first circuit layer and the insulating layer.

27. A printed circuit board comprising:
an insulating layer;
a via in the insulating layer;
a first circuit layer formed at a first side of the insulating layer and having a portion in the via; and
a second circuit layer formed at a second side of the insulating layer and electrically connected with the portion of the first circuit layer through the via.

28. The printed circuit board according to claim 27, wherein the first circuit layer has a second portion in a recessed portion of the insulating layer.

29. The printed circuit board according to claim 28, wherein a surface of the second portion facing away from the second side of the insulating layer is recessed from a surface of the first side of the insulating layer.

30. The printed circuit board according to claim 27, further comprising:
a solder resist formed on the first side of the insulating layer and covering over the portion of the first circuit layer; and
a solder resist formed on the second side of the insulating layer exposing a surface of the second circuit layer that is over the via while fully covering over other portions of the second circuit layer.

31. A method of manufacturing a printed circuit board, comprising:
forming a circuit pattern on a metal layer;
forming an insulating layer on the circuit pattern;
forming a via hole through the insulating layer that exposes a portion of the circuit pattern; and
forming a via in the via hole that buries the portion of the circuit pattern; and removing the metal layer to expose the circuit pattern.

32. The method of manufacturing a printed circuit board according to claim 31, further comprising:
prior to the forming the via hole, forming a second metal layer on a side of the insulating layer opposite to a side at which the circuit pattern is formed; and
after forming the via hole, forming a second circuit pattern on the second metal layer.

33. The method of manufacturing a printed circuit board according to claim 31, further comprising:
forming a portion of the circuit pattern to have a surface that is recessed from a surface of the insulating layer.
